(19) United States
(12) Patent Application Publication
(10) Pub. No.: US 2025/0343509 A1
(43) Pub. Date: Nov. 6, 2025

(54) DETECTION AND IDENTIFICATION OF WEAK SIGNALS IN A NOISY ENVIRONMENT

(71) Applicant: University of Central Florida Research Foundation, Inc., Orlando, FL (US)

(72) Inventors: Yehuda BRAIMAN, Orlando, FL (US); Gregg SCRANTON, Orlando, FL (US)

(21) Appl. No.: 18/653,408

(22) Filed: May 2, 2024

(51) Int. Cl. H03B 5/12

(52) U.S. Cl. CPC H03B 5/1234; H03B 5/1287

(57) ABSTRACT

A nonlinear design is described to reliably detect very weak signals buried in noisy environments and subject to environmental noises. This design does not require knowledge of prior data and is capable of detecting the amplitude and phase of the weak signal based on the data from a single sensor.

### FEDERALLY SPONSORED RESEARCH AND DEVELOPMENT

This invention was made with Government support under the Office of Naval Research, ONR Project N00014-20-1-2090. The Government has certain rights in the invention.

### BACKGROUND

The present application generally relates to the detection and identification of signals and more particularly, to the detection and identification of weak signals in a noisy environment.

Noise can degrade the quality of a signal and reduce the reliability and accuracy of measurements or communications. In signal processing and communication systems, various techniques are employed to mitigate the effects of noise, including filtering, modulation techniques, error correction coding, shielding, and noise-canceling algorithms.

Detection of weak signals in noisy environments is required for a wide variety of applications. On many occasions, signal propagation underwater and in the air will cause corruption and amplitude attenuation due to signal broadening and the effects of the propagation environment. Both underwater and atmospheric environments could be turbulent and cause signal corruption. Moreover, in many instances, the initial signals to detect are weak, consequently signals may not be detected. Consequently, environmental noises could be very damaging for detecting such weak signals.

### SUMMARY OF THE INVENTION

A nonlinear design is described to reliably detect very weak signals buried in noisy environments and subject to environmental noises. This design does not require knowledge of prior data and is capable of detecting the amplitude and phase of the weak signal based on the data from a single sensor.

Our presented designs indicate the feasibility of using a nonlinear dynamics-based methodology to detect very weak signals in noisy environments. A particular system of equations proposed may serve as a base for designing a reliable weak signal detection system. Due to nonlinearity, the same noise and noise plus signal data can be analyzed in different ways using the same equations but different realizations of parameter sets employing distinct dynamical states of the system. Additionally, since signals with the same frequency but different phases may be recorded on different sensors (employing sensor array), sensor array data could be a substantial addition for adding precision to the proposed detection designs.

Disclosed is a system and method to detect weak signals in a noisy environment. The method begins with operating a system of coupled oscillators. The system of coupled oscillators includes each of a left oscillator, a middle oscillator and a right oscillator with a given coupling strength among them, and the middle oscillator receives signal data with environmental noise data from at least one sensor to detect a signal at a frequency.

In one example, the right oscillator, the middle oscillator and the left oscillator are mathematically modeled by differential equations with a nonlinear term. For example, the nonlinear term is any one of sin(x), x², x³, or x⁴. It is important to note that other nonlinear terms may also be used.

Next the right oscillator and the left oscillator are driven with a user-selectable frequency equal to the frequency of the signal to detect.

Based on a function of the difference of the power spectrum of the left oscillator and a power spectrum of the right oscillator being equal to or above a settable threshold, using data from the sensor associated with the middle oscillator to detect the signal at the user selectable frequency and otherwise based on the difference between below a threshold ignoring the signal.

In one example, the right, middle, and left oscillators are mathematically modeled by second order differential equations with a sinusoidal nonlinear term. The data is time series data further comprising: iteratively performing for a settable number of iterations, each of i) applying a settable scaling factor to the sinusoidal nonlinear term that includes a noise and signal component for N number of samplings of time series data; and ii) calculating a detection coefficient P equal to a function. The N number of samplings of time series data may be a non-overlapping or partially overlapping time series data.

In one example, the detection coefficient P equal to a function is

$$P = \frac{1}{N} {\sum }_{j = 1}^{N} F [ ( {P}_{j 1} - {P}_{j 3} ) ] where F ( x ) is a function of ( {P}_{j 1} - {P}_{j 3} ) ;$$

where Pⱼ₁ is a value of a square root of the power spectrum of the left oscillator and Pⱼ₃ is a value of a square root of the power spectrum of the right oscillator at the user-selectable frequency.

In the event P is above the settable threshold, which is a nonzero threshold, using the data from the sensor associated with the middle oscillator to detect the signal at the user-selectable frequency and otherwise based on the difference between below a threshold ignoring the signal.

### BRIEF DESCRIPTION THE DRAWINGS

The invention, as well as a preferred mode of use and further objectives and advantages thereof, will best be understood by reference to the following detailed description of illustrative embodiments when read in conjunction with the accompanying drawings, wherein:

FIG. 1 is a diagram of an overall concept to carry out aspects of the present invention, middle oscillator is driven by signal plus noise;

FIG. 2 is a diagram of an overall concept to carry out aspects of the present invention of FIG. 1, middle oscillator is driven by noise only;

FIG. 3 is a functional block diagram of parallel simulations with different scaling factor values, according to one aspect of the present invention;

FIG. 4 is a graph of a scaling factor sweep demonstrating result of detection coefficient versus scaling factor, according to one aspect of the present invention;

FIG. 5 is a graph of matched filter results of matched filter coefficient versus total time duration, according to one aspect of the present invention;

FIG. 6 is a graph of the coupled oscillator method on the same sensor data of detection coefficient versus scaling factor, according to one aspect of the present invention;

FIG. 7, FIG. 9, and FIG. 10 are a series of graphs illustrating the dependence of the parameter P value on amplification factor C_{S} for different distributions of noise, according to one aspect of the present invention;

FIG. 8 is a graph produced by the instructions used to produce the experimental results, according to one aspect of the present invention; and

FIG. 11 is a system block diagram, according to one aspect of the present invention.

### DETAILED DESCRIPTION

### Non-Limiting Definitions

The terms “a”, “an” and “the” are intended to include the plural forms as well, unless the context clearly indicates otherwise.

The phrases “at least one of <A>, <B>, . . . and <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N, that is to say, any combination of one or more of the elements A, B, . . . or N including any one element alone or in combination with one or more of the other elements which may also include, in combination, additional elements not listed.

The term “coupled oscillators” refers to oscillators connected in such a way that energy can be transferred between them.

The term “first oscillator” is used interchangeably with “left oscillator,” denoting a relative position of this specific oscillator related to two other oscillators along a coordinate spectrum, such as a frequency spectrum. Likewise, the term “second oscillator” is used interchangeably with “middle oscillator” denoting this specific oscillator related to two other oscillators along the coordinate spectrum. The term “third oscillator” is used interchangeably with “right oscillator,” denoting a relative position of this specific oscillator related to two other oscillators along the coordinate spectrum.

The term “noise” refers to any unwanted or extraneous signal that interferes with the desired signal. It is essentially any random or unwanted variation in a signal that obscures the information being carried by the signal. Noise can be introduced at various stages in the signal's transmission, processing, or measurement, and it can arise from a variety of sources, both internal and external to the system. Some common sources of noise include thermal noise, interference such as electromagnetic interference (EMI) or radio frequency interference (RFI), quantization noise, shot noise due to diodes and transistors, thermal variations, vibrations, environmental noise, and other external factors that can introduce noise into sensitive systems.

The term “signal” refers to any physical quantity that varies over time, space, or any other independent variable and carries information. Signals can take many forms, including electrical signals, acoustic signals (sound waves), optical signals (light waves), mechanical signals (vibrations), and more.

### Overview

Although specific embodiments of the invention have been discussed, those having ordinary skill in the art will understand that changes can be made to the specific embodiments without departing from the scope of the invention. The scope of the invention is not to be restricted, therefore, to the specific embodiments, and it is intended that the appended claims cover any and all such applications, modifications, and embodiments within the scope of the present invention.

Disclosed is a method and system to identify and detect weak signals embedded in noisy data. Unlike other prior approaches, the system and method disclosed allow for detecting very weak signals, such that the amplitudes of the signals are well below the noise amplitudes. Moreover, the detection algorithm does not require knowledge of large sets of previous data. In fact, such data could be elusive since “noise” data may significantly change over time. It is possible to perform the entire detection process either computationally or integrated on very fast computer hardware to speed up detection time.

One aspect of the presently claimed invention is the detection of much weaker signals than signals detected with currently available typical signal processing technology. Another aspect of the claimed invention is the detection of both the amplitude and phase of periodic and/or pulse signals. Another aspect of the claimed invention is that it requires no prior knowledge about the noise. The claimed invention can be implemented based on the data from a single sensor or an array of sensors. Still, another aspect of the claimed invention is that detection errors, or the number of undetected signals, is minimal. The presently claimed invention provides the detection of weak signals in environmental noise required for various applications.

### Implementation Details

When fed by noise data, a nonlinear system can produce a substantially different response compared to a response from the same nonlinear system fed by noise and weak embedded signal. The addition of a very weak external signal to noise time series that drives an engineered nonlinear system may cause a strong response of such a system. This paradigm is used in the detection design. This detection technique involves several steps that offer a design for detecting weak signals. A system of coupled nonlinear differential equations that model nonlinear oscillators is employed. An important property of coupled nonlinear systems is that such systems may possess multiple substantially different solutions as system parameters change, and small changes in system parameters may lead to substantial changes in solutions.

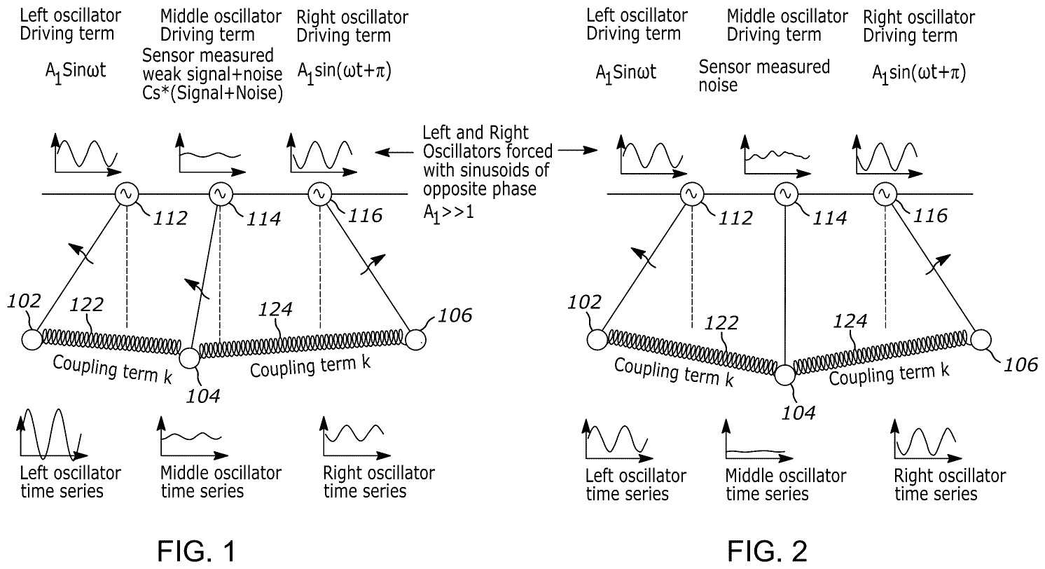

Turning now to FIG. 1 is a diagram of an overall concept to carry out aspects of the present invention. This conceptualized model is used to detect weak signals in noisy environments. Three pendulums are shown: a left pendulum, a middle pendulum, and a right pendulum. The left pendulum is driven by the term A₁ sin(ωt). The middle pendulum is driven accordingly to the term C_{S}*(Signal+Noise), where Cs is an iterating coefficient described further below. The right pendulum is driven by the same term as the left pendulum, just 180 degrees out of phase A₁ sin(ωt+π). This is illustrated by a snapshot of oscillatory motion in which the right pendulum is pulled to the right while the left pendulum and middle pendulum are pulled to the left. A set of springs are used to denote a coupling or mechanical coupling with coupling terms k between each pendulum in this conceptualized model. This term may be different for a different pendulums. The phase of the weak signal is constant. Thus, the difference of power spectra on the driving frequency (ω), S(dx₁/dt)−S(dx₃/dt) will depend on the phase of the weak signal.

Buried in environmental noise, a sensor-measured weak signal applied to the middle oscillator induces a substantially different response of the nonlinear coupled oscillator system compared to the response when only sensor-measured noise drives the middle oscillator. The weak signal phase is constant. Thus, the difference of power spectra on the driving frequency (ω), S(dx₁/dt)−S(dx₃/dt) will depend on the phase and frequency of the weak signal.

FIG. 2 is a diagram of an overall concept to carry out aspects of the present invention of FIG. 1, with the left oscillator and the right oscillator each driven with a nonlinear function with opposite phases. Statistically, the noise phase is not constant, thus its effect on the difference of power spectra on the driving frequency (ω). The S(dx₁/dt)−S(dx₃/dt) statistically averages to zero.

The three oscillators may be modeled as second-order differential equations with a nonlinear term, such as but not limited to a sinusoidal nonlinear term. The general principle used here is the following: a combined signal plus and noise time series are utilized as a forcing function for one oscillator, in this case, the middle oscillator, while the left and right oscillators are driven by artificial periodic and/or pulse signals that impose the dynamical state of the noiseless array. The distinctions in the system's responses to noise and noise and signal time series will indicate the presence of the signal.

Stated differently, the left oscillator and right oscillator are driven by an external signal at a specified amplitude and driven by the frequency of a signal to be detected. More specifically, the left oscillator and right oscillator are driven in the opposite direction or 180 degrees, e.g., It.

If the signal to be detected is present, it will be detected at the specified frequency by iterating a coefficient Cₛ that amplifies both the noise and the signal. A series of samples are taken for a specific coefficient. The square root of power spectrum of the left oscillator and the power spectrum of the right oscillator is computed. In response to the difference in power spectrum components of the left and right oscillators at the specified frequency being approximately zero, there is no signal, and there is just noise. However, if the difference in the power spectrum component at the specified frequency is above a settable threshold, the signal desired to be detected is present.

Consider the following set of differential equations:

In general terms, the right oscillator is modeled by

$${\ddot{x}}_{1} + {γ}_{1} {\dot{x}}_{1} + {α}_{1} F ( {x}_{1} ) = {I}_{1} + {κ}_{12} ( {x}_{2} - {x}_{1} ) + {A}_{1} sin ( ω t + {ϕ}_{1}$$

$${\ddot{x}}_{2} + {γ}_{2} {\dot{x}}_{2} + {α}_{2} F ( {x}_{2} ) = {I}_{2} + {κ}_{12} ( {x}_{1} - {x}_{2} ) + {κ}_{23} ( {x}_{3} - {x}_{2} ) + {C}_{s} ( Noise ( t ) + Signal ( t ) )$$

$${\ddot{x}}_{3} + {γ}_{3} {\dot{x}}_{3} + {α}_{3} F ( {x}_{3} ) = {I}_{3} + {κ}_{23} ( {x}_{2} - {x}_{3} ) + {A}_{3} sin ( ω t + {ϕ}_{3} + π )$$

F(x) is a nonlinear function.
   And, specifically, as an example,

$${\ddot{x}}_{1} + {γ}_{1} {\dot{x}}_{1} + {α}_{1} sin {x}_{1} = {I}_{1} + κ ( {x}_{2} - {x}_{1} ) + {A}_{1} sin ( ω t + {ϕ}_{1} )$$

$${\ddot{x}}_{2} + {γ}_{2} {\dot{x}}_{2} + {α}_{2} sin {x}_{2} = {I}_{2} + κ ( {x}_{3} - 2 {x}_{2} + {x}_{1} ) + {C}_{s} ( Noise ( t ) + Signal ( t ) )$$

$${\ddot{x}}_{3} + {γ}_{3} {\dot{x}}_{3} + {α}_{3} sin {x}_{3} = {I}_{3} + κ ( {x}_{2} - {x}_{3} ) + {A}_{3} sin ( ω t + {ϕ}_{3} + π )$$

$${γ}_{1} = {γ}_{3} , {α}_{1} = {α}_{3} , {I}_{1} = {I}_{3} , {A}_{1} = {A}_{3} , {ϕ}_{1} = {ϕ}_{3}$$

$${C}_{s} ( Noise ( t ) + Signal ( t ) ) = [ {A}_{2} sin ( ω t + {ϕ}_{2} ) + N ( t ) ]$$

The following notations,
α₁ is a coefficient of a nonlinear term of the right oscillator,
α₂ is a coefficient of a nonlinear term of the middle oscillator,
α₃ is a coefficient of the nonlinear term of the left oscillator,
A₁ is added signal modulation amplitude applied to the right oscillator,
A₂ an amplitude of the signal to be detected,
A₃ is added signal modulation amplitude applied to the left oscillator,
Cs is an iterating coefficient that multiplies both noise and signal,
I₁ is a torque (DC term) applied to the right oscillator.
I₂ is a torque (DC term) applied to the middle oscillator.
I₃ is a torque (DC term) applied to the left oscillator
κᵢⱼ is a coupling strength between oscillators i and j.
N(t) is a noise function,
ϕ₁ is an added modulation signal phase applied to the right oscillator,
ϕ₂ is a phase of the signal to be detected and applied to the middle oscillator,
ϕ₃ is a added modulation signal phase applied to the left oscillator,
t is time,
x₁ is a coordinate position of the right oscillator,
x₂ is a coordinate position of the middle oscillator,
x₃ is a coordinate position of the left oscillator,
\dot{x} a first derivative of x,
\ddot{x} is a second derivative of x,
ω is a frequency of a desired signal to be detected,
γ₁ is a dissipation coefficient applied to the right oscillator,
γ₂ is a dissipation coefficient applied to the middle oscillator,
γ₃ is a dissipation coefficient applied to the left oscillator.

Here, κᵢⱼ determines the coupling strength between oscillators i and j. The left and right oscillators are driven by periodic excitation with thoroughly constructed amplitude and phase. The function is the noise function that drives the middle oscillator. If there is a weak external signal in noisy data, this signal will drive the middle oscillator as well. Accordingly, Cs is a coefficient that multiplies both noise and signal (if such is present) to act as the amplification factor.

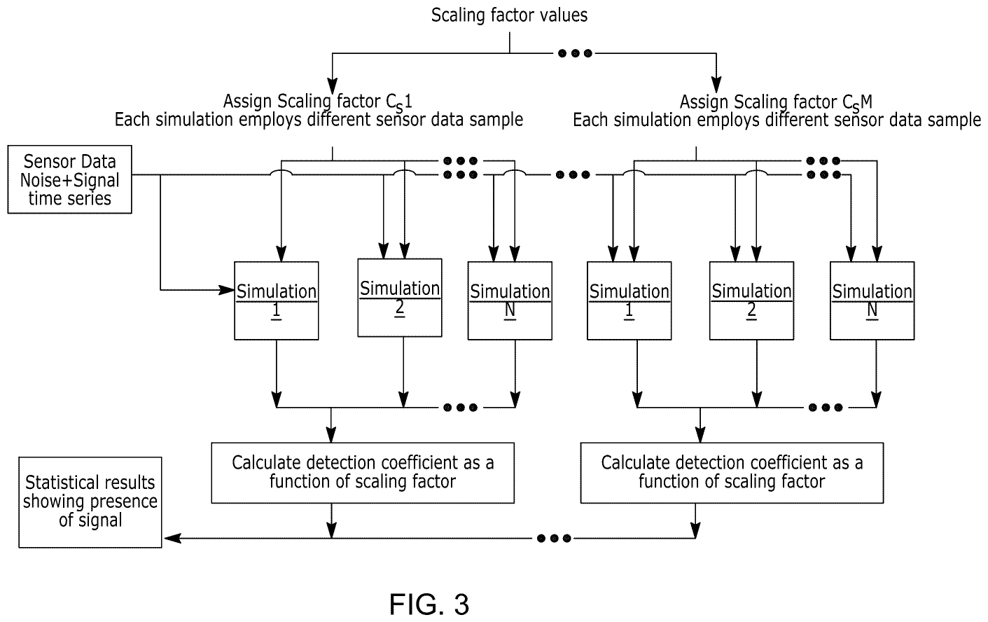

FIG. 3 is a functional block diagram of simulations with different scaling factor values. Simulations are executed in parallel for each combination of scaling factor and sensor data sample. The detection coefficient P for each scaling factor is calculated using the results from all sensor data samples. The resulting set of detection coefficients P is plotted against the scaling factor to show the presence of a signal. If no signal is present, coefficients remain near zero. If a signal is present, coefficients will average a significant nonzero value.

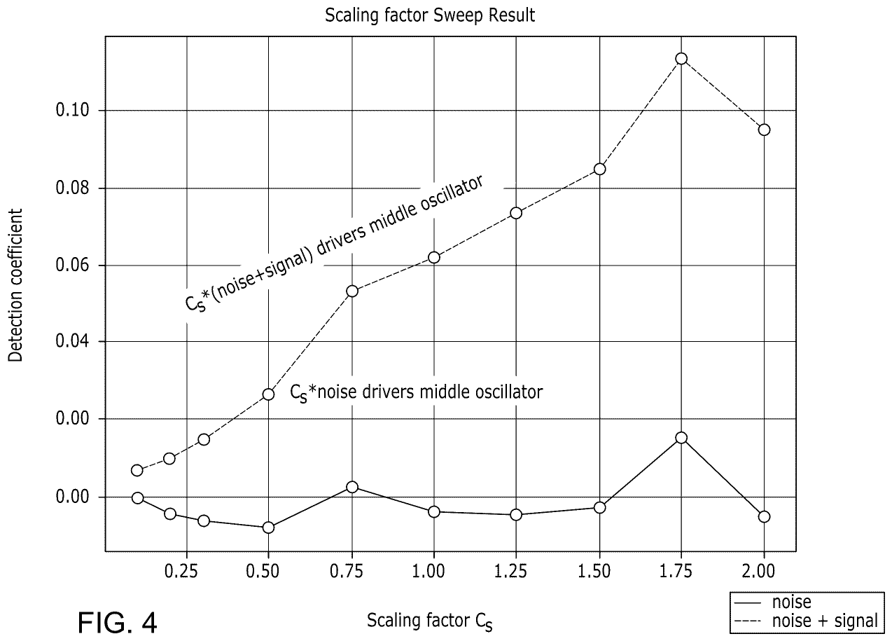

FIG. 4 is a graph of a scaling factor sweep result of detection coefficient P versus scaling factor Cs. This can be a periodic and/or pulse signal.

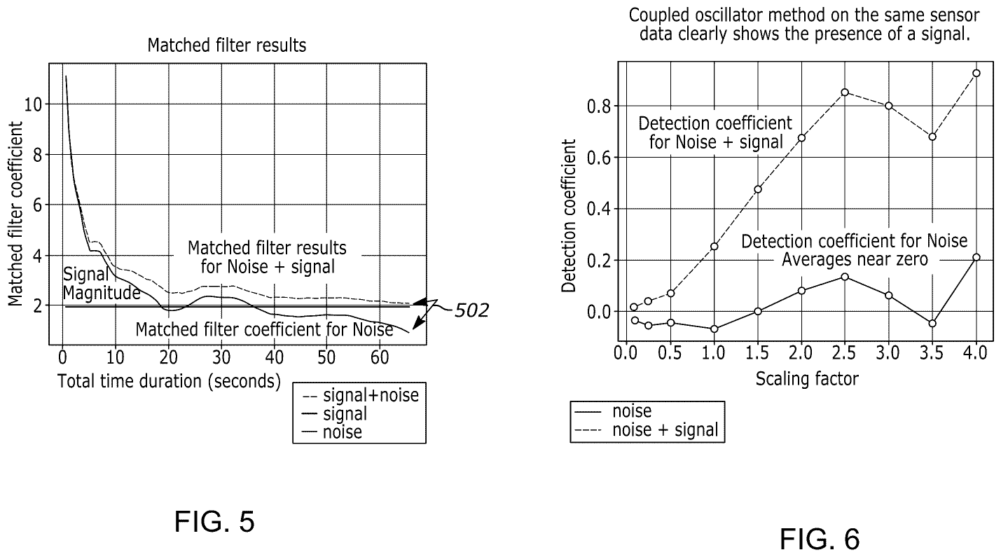

FIG. 5 is a graph of matched filter results of matched filter coefficient versus total time duration. The matched filter coefficient is the square root of the power spectrum at the frequency of detection, averaged over 100 samplings with different time shifts. The matched filter run shows signal+noise converging near the signal value and the noise converging to a lower value, possibly giving a false positive.

FIG. 6 is a graph of the coupled oscillator method on the same sensor data of detection coefficient versus scaling factor. The coupled oscillator method on the same sensor data clearly shows the presence of a signal.

Detection coefficient, also referred to as parameter P, is defined as

$$P = \frac{1}{N} {\sum }_{j = 1}^{N} ( {P}_{j 1} - {P}_{j 3} )$$

where Pij is the value of the square root of the power spectrum of the x-derivative at the frequency of detection and N is the number of the samplings. Coefficient values are averaged for N repetitions, each with a different realization of noise and signal sequence.

The system is prepared in a state where, in the absence of noise, the middle oscillator power spectrum does not have a signal component of the frequency for a signal we are looking for, while the left and right oscillators are periodically modulated by a term with the frequency we are interested in detecting. Additionally, a nearby solution (which may not be stable) exists where the second oscillator time derivative has a component of the frequency being detected and identified. However, driving by just noise will not induce any transition in the dynamic state of the system. This is an important observation. Then, a very tiny signal at the desired frequency driving the middle oscillator may cause the system to transition to a nearby state. This driving should be selective such that a small signal amplitude driving the system with other than the desired frequency will not cause the transition. This design requires careful system parameter choice and, consequently, careful exploration of the parameter space to observe the described effect. Indeed, improper choice of parameters will wipe out any effect, and nothing significant will be observed.

The value of parameter P depends on the phase of the signal applied to the middle oscillator. If the middle oscillator is driven by noise only, P should average to zero over multiple realizations of noise. If there is an embedded signal in noise data, we observe a nonzero value for P.

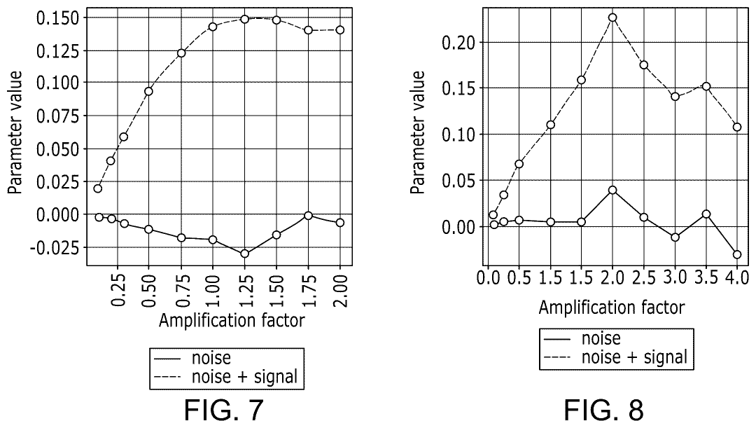

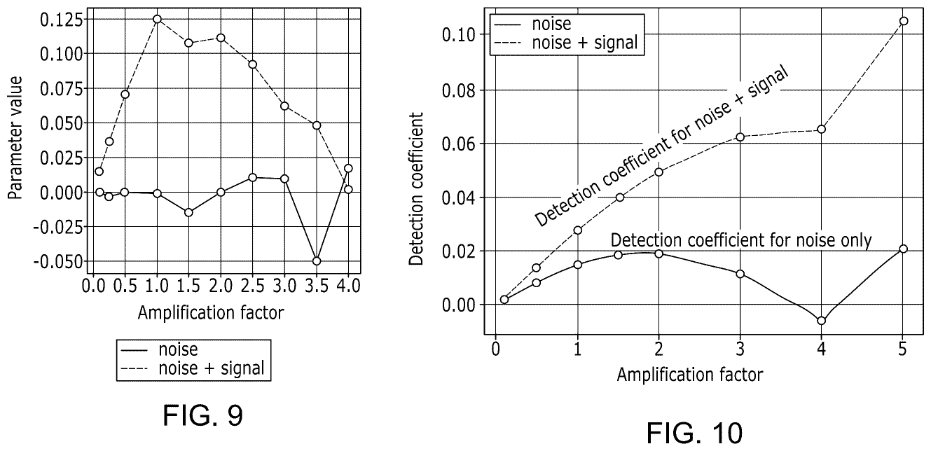

The inventors have studied the dependence of parameter P on amplification factor C_{S} for just noise and noise plus signal data employing an ˜0 dB signal applied to the middle oscillator. For each value of the amplification factor, we conducted 10-100 different simulations with different values of time shift for the noise (hereafter referred to as noise sampling). In this study, four different distributions of noise data that were available are used. The sweep depicted in FIG. 7 used synthetic noise that mimics environmental noise data. The sweep depicted in FIG. 8 used data randomly generated from a uniform distribution. The sweep depicted in FIG. 9 used data randomly generated from a Gaussian distribution. The sweep depicted in FIG. 7 used data from a source of environmental noise. The parameter P value as a function of the amplification factor is presented in FIG. 7, FIG. 8, and FIG. 9. For the curve in FIG. 7, noise sampling was equal to 100. For the curve in FIG. 8, noise sampling was equal to 20. For the curve in FIG. 10, the noise sampling was equal to 10, and for the curve FIG. 9, the noise sampling was equal to 40. For each simulation in the sweeps represented in FIG. 7 through FIG. 9, 2²⁰ data points were used for the Fourier transform to calculate the parameter P. For each simulation in the sweep represented in FIG. 10, 40,000 data points were used for the Fourier transform to calculate the parameter P.

As seen in FIG. 7 through FIG. 10, the value of the parameter P for noise data sampling only stays near zero and is statistically independent of the amplification factor. On the other hand, the value of parameter P for signal plus noise data sampling is nonzero and initially increases with the amplification factor. This property can be used for weak signal detection design.

### Procedure to Replicate Sweep Results

Use the following set of differential equations.

$${\ddot{x}}_{1} + {γ}_{1} {\dot{x}}_{1} + {α}_{1} F ( {x}_{1} ) = {I}_{1} + κ ( {x}_{2} - {x}_{1} ) + {A}_{1} sin ( ω t + {ϕ}_{1} ) ;$$

$${\ddot{x}}_{2} + {γ}_{2} {\dot{x}}_{2} + {α}_{2} F ( {x}_{2} ) = {I}_{2} + κ ( {x}_{3} - 2 {x}_{2} + {x}_{1} ) + {C}_{s} ( Noise ( t ) + Signal ( t ) ) ;$$

$${\ddot{x}}_{3} + {γ}_{3} {\dot{x}}_{3} + {α}_{3} F ( {x}_{3} ) = {I}_{3} + κ ( {x}_{2} - {x}_{3} ) + {A}_{3} sin ( ω t + {ϕ}_{3} + π ) ;$$

Where F is a nonlinear sin function.

$$Signal ( t ) = {A}_{2} sin ( ω t + {ϕ}_{2} )$$

$${γ}_{1} = {γ}_{3} = 0.7$$

$${γ}_{2} = 1.1$$

$${α}_{1} = {α}_{2} = {α}_{3} = 1 {0}^{4}$$

$${I}_{1} = {I}_{2} = {I}_{3} = 1$$

$$κ = 300$$

$${A}_{1} = {A}_{3} = 1 {0}^{3}$$

$${C}_{n} = 1 {0}^{4}$$

$$f = 14.7003 , ω = 2 π f$$

$${ϕ}_{1} = {ϕ}_{2} = {ϕ}_{3} = 0$$

Cs is set to different values (see below)
A₂=0 (no signal) or external signal value (with signal)

Solve using the fourth-order Runge-Kutta method.

The noise data is a time series generated from a uniform distribution with a time step of 6.25×10⁻⁴, and a total time of 2000. The time series is then lowpass filtered with a cutoff frequency of 30 Hz.
Step 1: Set A₂=0 so that only noise is applied to the second oscillator. Apply a scaling factor C_{S}=0.1 to the noise data. Integrate the equations from t=0.0 s to t=900.0 s. Use a timestep of 1.5625×10⁻⁴ s for integration. This is 4 times smaller than the noise data time step of 6.25×10⁻⁴ s. For the integration steps between noise data points, use cubic spline interpolation between noise data points to approximate the noise data value. Set the initial conditions for all oscillators and their derivatives to zero.

Once integration is complete, keep only the data on the same grid as the noise data, with a timestep of 6.25×10⁻⁴ s. Calculate the power spectrum of \dot{x}₁ and \dot{x}₃ using only the last 655.36 seconds of the time series (2²⁰ data points). Calculate the detection coefficient component D₁=P₁₁−P₁₃, where P₁ᵢ is the square root of the power spectrum component at the driving frequency, 14.7003 Hz, on the ith oscillator.
Step 2: Repeat step 1 nineteen more times across different time intervals, using the same methods and same initial conditions. For each successive time interval, add 90.134375 s to the start time, relative to the last start time. This number is chosen because it is divisible by the period 1/f. The ending time should be 900 s after the start time. It is important to note that the increment between sequential time intervals must be divisible by the period of the driving frequency, 1/f, where f is 14.7003 Hz. This ensures the signal at this frequency will have the same phase in each time interval.

It is important to note that the increment between sequential time intervals must be divisible by the period of the driving frequency, 1/f, where f is 14.7003 Hz. This ensures the signal at this frequency will have the same phase in each time interval.

For each time interval, calculate the power spectrum of \dot{x}₁ and \dot{x}₃ using only the last 655.36 seconds of the time series (2²⁰ data points). Calculate the detection coefficient component Dⱼ=Pⱼ₁−Pⱼ₃, where Pⱼᵢ is the square root of the power spectrum component at the driving frequency, 14.7003 Hz, on the ith oscillator, for the jth time interval.
Step 3: Once each P component is calculated, calculate the averaged detection coefficient (N=20).

$$P = \frac{1}{N} {\sum }_{j = 1}^{N} ( {P}_{j 1} - {P}_{j 3} )$$

Step 4: Change the scaling factor, C_{S}, applied to the noise, and repeat steps 1-3. Repeat for the following scaling factors: 0.25, 0.5, 1.0, 1.5, 2.0, 2.5, 3.0, 3.5, 4.0. This will result in an averaged detection coefficient for each scaling factor.
Step 5: In the oscillator equations, set A₂=0.42 to add a signal at ˜0 dB relative to the noise. Repeat steps 1-4 with this A₂ value. C_{S} is applied to both signal and noise in this case. This will result in eight detection coefficient values for different scaling factor values for the case with signal and noise. A plot of all detection coefficients should match FIG. 8.

In one example, the function Pⱼ₁ may be raised to any odd exponential power in order to preserve its positive sign or negative sign.

### System Block Diagram

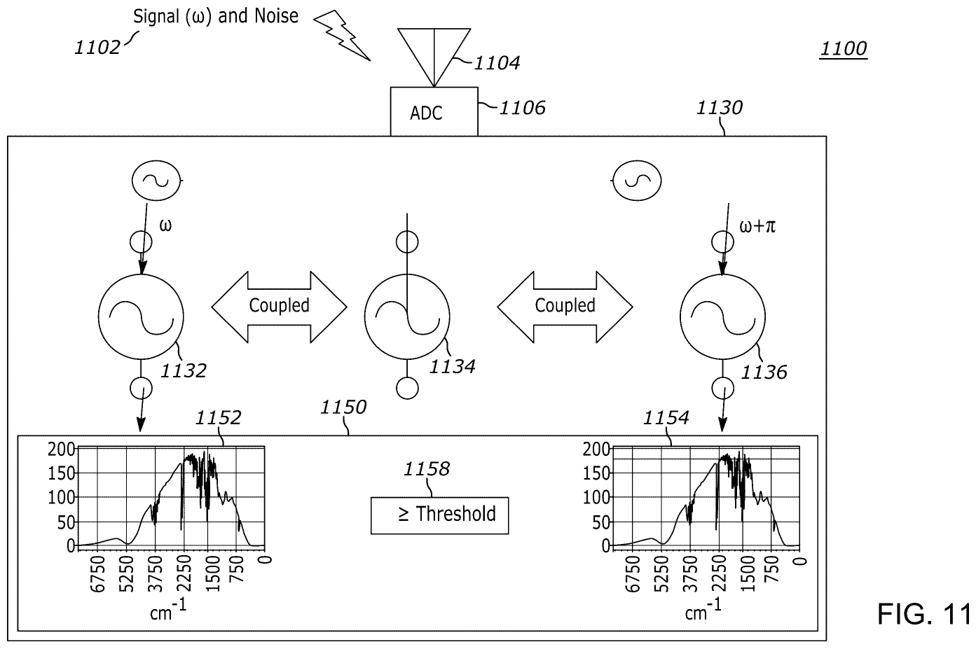

FIG. 11 is a system block diagram 1100. It is possible to perform the entire detection process either computationally or integrated on very fast computer hardware such as a Digital Signal Processor (DSP) 1130 to speed up detection time.

The input of the DSP 1130 is electrically coupled to an analog-to-digital converter 1106, which is coupled to an antenna 1104. The antenna receives the signal as frequency ω with noise, as shown. The DSP 1130 operates by manipulating information that has been converted into a digital format, representing complex data or signals as a sequence of binary numbers. In this example, the DSP is capable of mathematically implementing the differential equations discussed above for each of the left, middle, and right coupled oscillators 1132, 1134, and 1136. The left oscillator 1132 is driven at a frequency ω, which is equal to the desired signal to be detected. The right oscillator is driven at the same frequency ω but 180 degrees out-of-phase.

The DSP 1130 enables the precise and efficient manipulation of these signals to improve, modify, or analyze their characteristics. At the heart of a DSP's functionality is its ability to perform high-speed mathematical operations on digital signals. These operations include additions, multiplications, and subtractions, executed at very high speeds. The DSP takes in digital input signals, processes them based on a set of algorithms or instructions, and then outputs the modified signals. These algorithms can vary widely depending on the application, ranging from noise reduction and echo cancellation in telecommunications to image processing and compression in multimedia applications. In this example, the DSP 1130 includes a power spectrum algorithm or circuit to calculate the difference between the power spectrum of the left oscillator 1152 and the power spectrum of the right oscillator 1156. If the difference calculated is equal to or above a settable threshold 1158, the data received from antenna 1104 is detected. Otherwise, if the difference calculated is below the settable threshold, the signal will be ignored.

A typical DSP system includes several key components: a processor, memory blocks for data and instructions, and input/output interfaces. The processor, often designed with specialized architectural features like multiple execution units and hardware multipliers, is optimized for the rapid execution of computational tasks common in signal processing. Memory blocks are crucial for storing the digital signals to be processed, as well as the algorithms and programs that define the processing steps. Input/output interfaces allow the DSP to communicate with the external world, receiving digital signals from sensors or other sources and sending out processed signals to other devices or systems. The efficiency and flexibility of DSPs stem from their ability to execute complex digital signal processing algorithms in real-time, making them indispensable in a wide range of applications from consumer electronics to industrial control systems.

### Non-Limiting Examples

Although specific embodiments of the invention have been discussed, those having ordinary skill in the art will understand that changes can be made to the specific embodiments without departing from the scope of the invention. The scope of the invention is not to be restricted, therefore, to the specific embodiments, and it is intended that the appended claims cover any and all such applications, modifications, and embodiments within the scope of the present invention.

It should be noted that some features of the present invention may be used in one embodiment thereof without use of other features of the present invention. As such, the foregoing description should be considered as merely illustrative of the principles, teachings, examples, and exemplary embodiments of the present invention, and not a limitation thereof.

Also, these embodiments are only examples of the many advantageous uses of the innovative teachings herein. In general, statements made in the specification of the present application do not necessarily limit any of the various claimed inventions. Moreover, some statements may apply to some inventive features but not to others.

The description of the present invention has been presented for purposes of illustration and description, and is not intended to be exhaustive or limited to the invention in the form disclosed. Many modifications and variations will be apparent to those of ordinary skill in the art without departing from the scope and spirit of the described embodiments. The embodiment was chosen and described in order to best explain the principles of the invention, the practical application, and to enable others of ordinary skill in the art to understand the invention for various embodiments with various modifications as are suited to the particular use contemplated. The terminology used herein was chosen to best explain the principles of the embodiments, the practical application or technical improvement over technologies found in the marketplace, or to enable others of ordinary skill in the art to understand the embodiments disclosed herein.

### INCORPORATED REFERENCES

The following publications are each incorporated by reference in their entirety and listed in the Information Disclosure:
[1] Eli Brosh, Matan Friedmann, Ilan Kadar, Lev Yitzhak Lavy, Elad Levi, Shmuel Rippa, Yair Lempert, Bruno Fernandez-Ruiz, Roei Herzig, and Trevor Darrell. Accurate visual localization for automotive applications. In Proceedings of the IEEE Conference on Computer Vision and Pattern Recognition Workshops, pages 0-0, 2019.
[2] Arie Sheinker, Ariel Shkalim, Nizan Salomonski, Boris Ginzburg, Lev Frumkis, Ben-Zion Kaplan. Processing of a scalar magnetometer contaminated by 1/f a noise. Sensors and Actuators A 138 (2007) 105-111.

What is claimed is:

1. A method to detect weak signals in a noisy environment, the method comprising:
operating a system of coupled oscillators, the system includes each of a left oscillator, a middle oscillator and a right oscillator with a given coupling strength among them, and the middle oscillator receiving signal data with environmental noise data from at least one sensor to detect a signal at a frequency;
driving the right oscillator and the left oscillator with a user-selectable frequency equal to the frequency of the signal to detect; and
based on a function of the difference of a power spectrum of the left oscillator and a power spectrum of the right oscillator being equal to or above a settable threshold, using data from the sensor associated with the middle oscillator to detect the signal at the user selectable frequency and otherwise based on the difference between below a threshold ignoring the signal.

2. The method of claim 1,
wherein the right oscillator, the middle oscillator and the left oscillator are mathematically modeled by differential equations with a sinusoidal nonlinear term; and
wherein the data is time series data further comprising:
iteratively performing for a settable number of iterations, each of
applying a settable scaling factor to the sinusoidal nonlinear term that includes a noise and signal component for N number of samplings of time series data;
calculating a detection coefficient P equal to a function.

3. The method of claim 2, wherein the N number of samplings of time series data is a non-overlapping or partially overlapping time series data.

4. The method of claim 2, wherein the detection coefficient P equal to a function is
$$P = \frac{1}{N} {\sum }_{j = 1}^{N} F [ ( {P}_{j 1} - {P}_{j 3} ) ]$$
$$F ( x ) is a function of ( {P}_{j 1} - {P}_{j 3} ) ;$$
where Pⱼ₁ is a value of a square root of the power spectrum of the left oscillator and Pⱼ₃ is a value of a square root of the power spectrum of the right oscillator at the user-selectable frequency; and
in the event P is above the settable threshold, which is a nonzero threshold, using the data from the sensor associated with the middle oscillator to detect the signal at the user selectable frequency and otherwise based on the difference between below a threshold ignoring the signal.

5. The method of claim 1, wherein the right oscillator, the middle oscillator and the left oscillator are mathematically modeled by differential equations with a nonlinear term.

6. The method of claim 5, wherein the nonlinear term is any one of sin(x), x², x³ or x⁴.

7. The method of claim 5, wherein
the right oscillator is modeled by
$${\ddot{x}}_{1} + {γ}_{1} {\dot{x}}_{1} + {α}_{1} F ( {x}_{1} ) = {I}_{1} + {κ}_{12} ( {x}_{2} - {x}_{1} ) + {A}_{1} sin ( ω t + {ϕ}_{1} )$$
the middle oscillator is modeled by
$${\ddot{x}}_{2} + {γ}_{2} {\dot{x}}_{2} + {α}_{2} F ( {x}_{2} ) = {I}_{2} + {κ}_{12} ( {x}_{1} - {x}_{2} ) + {κ}_{23} ( {x}_{3} - {x}_{2} ) + {C}_{s} ( Noise ( t ) + Signal ( t ) )$$
the left oscillator is modeled by
$${\ddot{x}}_{3} + {γ}_{3} {\dot{x}}_{3} + {α}_{3} F ( {x}_{3} ) = {I}_{3} + {κ}_{23} ( {x}_{2} - {x}_{3} ) + {A}_{3} sin ( ω t + {ϕ}_{3} + π )$$
$${γ}_{1} = {γ}_{3} , {α}_{1} = {α}_{3} , {I}_{1} = {I}_{3} , {A}_{1} = {A}_{3} , {ϕ}_{1} = {ϕ}_{3} ;$$
$${C}_{s} ( Noise ( t ) + Signal ( t ) ) = [ {A}_{2} sin ( ω t + {ϕ}_{2} ) + N ( t ) ] ;$$
F(x) is a nonlinear function;
wherein
α₁ is a coefficient of a nonlinear term of the right oscillator,
α₂ is a coefficient of a nonlinear term of the middle oscillator,
α₃ is a coefficient of the nonlinear term of the left oscillator,
A₁ is added signal modulation amplitude applied to the right oscillator,
A₂ an amplitude of the signal to be detected,
A₃ is added signal modulation amplitude applied to the left oscillator,
Cs is a coefficient that multiplies both noise and signal,
I₁ is a torque (DC term) applied to the right oscillator.
I₂ is a torque (DC term) applied to the middle oscillator.
I₃ is a torque (DC term) applied to the left oscillator
κᵢⱼ is a coupling strength between oscillators i and j,
N(t) is a noise function,
ϕ₁ is an added modulation signal phase applied to the right oscillator,
ϕ₂ is a phase of the signal to be detected applied to the middle oscillator,
ϕ₃ is a added modulation signal phase applied to the left oscillator,
t is time,
x₁ is a coordinate position of the right oscillator,
x₂ is a coordinate position of the middle oscillator,
x₃ is a coordinate position of the left oscillator,
\dot{x} is a first derivative of x,
\ddot{x} is a second derivative of x,
ω is a frequency of a desired signal to be detected,
γ₁ is a dissipation coefficient applied to the right oscillator,
γ₂ is a dissipation coefficient applied to the middle oscillator,
γ₃ is a dissipation coefficient applied to the left oscillator.

8. The method of claim 7, wherein F(x) is sin(x).

9. The method of claim 1, wherein the signal is transmitted in an atmospheric environment.

10. The method of claim 1, wherein the signal is transmitted in an underwater environment.

11. A system to detect weak signals in a noisy environment, the system comprising:
a left oscillator;
a middle oscillator receiving signal data with environmental noise data from at least one sensor to detect a signal at a frequency;
a right oscillator with a given coupling strength between each of the left oscillator, the middle oscillator and the right oscillator;
a frequency generator to drive the right oscillator and the left oscillator with a user-selectable frequency equal to the frequency of the signal to detect; and
a power spectrum circuit to calculate a function of the difference of a power spectrum of the left oscillator and a power spectrum of the right oscillator being equal to or above a settable threshold, using data from the sensor associated with the middle oscillator to detect the signal at the user selectable frequency and otherwise based on the difference between below a threshold ignoring the signal.

12. The system of claim 11,
wherein the right oscillator, the middle oscillator and the left oscillator are mathematically modeled by differential equations with a sinusoidal nonlinear term; and
wherein the data is time series data further comprising:
iteratively performing for a settable number of iterations, each of
applying a settable scaling factor to the sinusoidal nonlinear term that includes a noise and signal component for N number of samplings of time series data;
calculating a detection coefficient P equal to a function.

13. The system of claim 12, wherein the N number of samplings of time series data is a non-overlapping or partially overlapping time series data.

14. The system of claim 12, wherein the detection coefficient P equal to a function is
$$P = \frac{1}{N} {\sum }_{j = 1}^{N} F [ ( {P}_{j 1} - {P}_{j 3} ) ]$$
F(x) is a function of (Pⱼ₁−Pⱼ₃);
where Pⱼ₁ is a value of a square root of the power spectrum of the left oscillator and Pⱼ₃ is a value of a square root of the power spectrum of the right oscillator at the user-selectable frequency; and
in the event P is above the settable threshold, which is a nonzero threshold, using the data from the sensor associated with the middle oscillator to detect the signal at the user selectable frequency and otherwise based on the difference between below a threshold ignoring the signal.

15. The system of claim 11, wherein the right oscillator, the middle oscillator and the left oscillator are mathematically modeled by differential equations with a nonlinear term.

16. The system of claim 15, wherein the nonlinear term is any one of sin(x), x², x³ or x⁴.

17. The system of claim 15, wherein
the right oscillator is modeled by
$${\ddot{x}}_{1} + {γ}_{1} {\dot{x}}_{1} + {α}_{I} F ( {x}_{1} ) = {I}_{1} + {κ}_{12} ( {x}_{2} - {x}_{1} ) + {A}_{1} sin ( ω t + {ϕ}_{1} )$$
the middle oscillator is modeled by
$${\ddot{x}}_{2} + {γ}_{2} {\dot{x}}_{2} + {α}_{2} F ( {x}_{2} ) = {I}_{2} + {κ}_{12} ( {x}_{1} - {x}_{2} ) + {κ}_{23} ( {x}_{3} - {x}_{2} ) + {C}_{s} ( Noise ( t ) + Signal ( t ) )$$
the left oscillator is modeled by
$${\ddot{x}}_{3} + {γ}_{3} {\dot{x}}_{3} + {α}_{3} F ( {x}_{3} ) = {I}_{3} + {κ}_{23} ( {x}_{2} - {x}_{3} ) + {A}_{3} sin ( ω t + {ϕ}_{3} + π )$$
$${γ}_{1} = {γ}_{3} , {α}_{1} = {α}_{3} , {I}_{1} = {I}_{3} , {A}_{1} = {A}_{3} , {ϕ}_{1} = {ϕ}_{3} ;$$
$${C}_{s} ( Noise ( t ) + Signal ( t ) ) = [ {A}_{2} sin ( ω t + {ϕ}_{2} ) + N ( t ) ] ;$$
F(x) is a nonlinear function;
wherein
α₁ is a coefficient of a nonlinear term of the right oscillator,
α₂ is a coefficient of a nonlinear term of the middle oscillator,
α₃ is a coefficient of the nonlinear term of the left oscillator,
A₁ is added signal modulation amplitude applied to the right oscillator,
A₂ an amplitude of the signal to be detected,
A₃ is added signal modulation amplitude applied to the left oscillator,
Cs is a coefficient that multiplies both noise and signal,
I₁ is a torque (DC term) applied to the right oscillator.
I₂ is a torque (DC term) applied to the middle oscillator.
I₃ is a torque (DC term) applied to the left oscillator
κᵢⱼ is a coupling strength between oscillators i and j,
N(t) is a noise function,
ϕ₁ is an added modulation signal phase applied to the right oscillator,
ϕ₂ is a phase of the signal to be detected applied to the middle oscillator,
ϕ₃ is a added modulation signal phase applied to the left oscillator,
t is time,
x₁ is a coordinate position of the right oscillator,
x₂ is a coordinate position of the middle oscillator,
x₃ is a coordinate position of the left oscillator,
\dot{x} a first derivative of x,
\ddot{x} is a second derivative of x,
ω is a frequency of a desired signal to be detected,
γ₁ is a dissipation coefficient applied to the right oscillator,
γ₂ is a dissipation coefficient applied to the middle oscillator,
γ₃ is a dissipation coefficient applied to the left oscillator.

18. The system of claim 17, wherein F(x) is sin(x).

19. The system of claim 11, wherein the signal is transmitted in an atmospheric environment.

20. The system of claim 11, wherein the signal is transmitted in an underwater environment.
